(19) United States
(12) Patent Application Publication
(10) Pub. No.: US 2023/0301204 A1
(43) Pub. Date: Sep. 21, 2023

(54) MEMRISTOR AND MEMRISTIVE DEVICES VIA NITROGEN GAS BASED SPUTTER DEPOSITION ENABLING DIFFUSION OF METAL INTO METAL OR METALLOID NITRIDES AND ALLOYS

(71) Applicants: Joel Yi Yang Loh, Toronto (CA); Andres Esteban Lombo, Oakville (CA); Nazir Pyarali Kherani, Toronto (CA); Samuel Brooke Moor-Smith, Richmond (CA); Richard James Curry, Macclesfield (GB)

(72) Inventors: Joel Yi Yang Loh, Toronto (CA); Andres Esteban Lombo, Oakville (CA); Nazir Pyarali Kherani, Toronto (CA); Samuel Brooke Moor-Smith, Richmond (CA); Richard James Curry, Macclesfield (GB)

(21) Appl. No.: 18/109,537

(22) Filed: Feb. 14, 2023

Related U.S. Application Data
(60) Provisional application No. 63/310,013, filed on Feb. 14, 2022.

(51) Int. Cl. H10N 70/00; G06N 3/063

(52) U.S. Cl. CPC H10N 70/026; G06N 3/063

(57) ABSTRACT

Devices and methods are provided for controlling metallic diffusion and filamentation within a metal nitride layer from a preceding metal layer, via nitrogen plasma sputter deposition of the metal layer. In some embodiments, sputtering parameters are selected to introduce nitrogen gas into the metal layer such that nitrogen outgassing from the metal layer into the metal nitride layer generates a metal concentration profile. In the embodiments the metal diffused layers are shown to exhibit memristive behaviour in vertical, diagonal or laterally configured devices. Methods are provided for additional control of the metal concentration profile via other deposition methods. Various memristor designs are provided to utilize silver filamentation in an aluminum nitride memristor platform. The basic approach can be extended to the use of other noble metals and metals in general, as well as alloys and eutectics where concentration dependent chemistry can be appropriately availed in various ways including ionic transport.

### CROSS-REFERENCE TO RELATED APPLICATIONS

This application claims priority to U.S. Provisional Patent Application No. 63/310,013, titled “MEMRISTOR AND MEMRISTIVE DEVICES VIA NITROGEN GAS BASED SPUTTER DEPOSITION ENABLING DIFFUSION OF METAL INTO METAL OR METALLOID NITRIDES AND ALLOYS” and filed on Feb. 14, 2022, the entire contents of which is incorporated herein by reference.

### BACKGROUND

The present disclosure relates to the fabrication of memristor devices, in particular metal filamentation in a metal nitride layer via sputtering with nitrogen-based plasma or plasma mixtures.

### SUMMARY

Methods and devices are provided herein for controlling the metal diffusion concentration profile within a nitride dielectric material via introducing nitrogen gas during the sputtering of the preceding metal layer. In some embodiments, the method of nitrogen induced metal diffusion and its mechanism is described, and additional fabrication methods are provided to complement the method. In some embodiments, device designs that implement the nitrogen induced metal diffusion for memristance applications are provided. An example implementation of nitrogen induced silver diffusion into an aluminum nitride layer and its associated electrical behaviour is described.

Accordingly, in one aspect, there is provided a method for inducing metal diffusion into the nitride layer, the resulting layers of interest comprise:
a substrate and a layer of electrode material; and
a thin metal layer that is sputter deposited with a mixture of nitrogen/inert gas plasma, such that nitrogen gas is incorporated as an impurity within the metal layer; and
a thin metal nitride layer that was sputter deposited with a mixture of nitrogen/inert gas plasma, or with other reactive gases such that a compositionally stable metal nitride layer sits on top of the metal layer; and
the incorporated nitrogen within the metal layer source is able to induce metallic diffusion into the metal nitride layer through the formation of nitrogen gas induced micro voids or other defects; and
the resulting metal nitride layer as a non-zero amount of metal introduced as elementally diffused, or partially or fully formed metal filamentation nanostructures; and
wherein the metal that has diffused from the underlying film into metal nitride film are able to extend or expand under a voltage bias that enables more metal diffusion to occur from the metal layer source; and
such that an electric current can flow between the metal layer and the top of the metal nitride layer; and
wherein the metal filamentation nanostructures can break apart under a reversed voltage bias; and
such that an electric current is unable to flow between the metal layer and the top of the metal nitride layer.

In another aspect, there are additional modifications to the sputtering method such as co-sputtering, ion-implantation and chemical vapor deposition.

In another aspect, there is provided a memristor device comprising:
electrodes deposited below and on top of the metal nitride/metal layers, with a lateral offset such that the electrodes do not form a vertical direct path; and
wherein a voltage bias between the electrodes induces metal filamentation in the metal nitride/metal layer; and
such that metal filamentation proceeds both diagonally within the metal nitride layer.

In another aspect, there is provided a memristor device comprising:
laterally deposited electrodes; and
a metal nitride/metal layer deposited between the lateral deposited electrodes; and
wherein a voltage bias between the electrodes induces metal filamentation in the metal nitride/metal layer; and
such that metal filamentation proceeds both vertically and laterally within and on the metal nitride layer.

In another aspect, there is provided a memristor device comprising:
vertically deposited electrodes; and
a metal nitride/metal layer deposited between the vertical deposited electrodes; and
such that structures that comprises a plurality of vertically arrayed electrodes and metal nitride/metal layers;
wherein a neural network is implemented in such a crossbar device.

In another aspect, there is provided a memristor device comprising:
laterally deposited electrodes; and
a metal nitride/metal layer deposited between the lateral deposited electrodes; and
such that structures that comprises a plurality of laterally arrayed electrodes and metal nitride/metal layers;
wherein a neural network is implemented in a grid network or in a multi-junction terminal network resembling the structure of a biological synapse junction.

In another aspect, there is provided a method of minimum spanning tree of weighted graphs with a greedy approach, which comprises:
each vertex can be stored in a binary on or off state;
further comprising the shortest edge is evaluated which also does not generate a cycle with adjacent edges; and
further comprising the available edges will be set to the on state while non-available edges are set to the off stage so that the tree does not include those edges.

A further understanding of the functional and advantageous aspects of the disclosure can be realized by reference to the following detailed description and drawings.

### BRIEF DESCRIPTION OF THE DRAWINGS

Embodiments will now be described, by way of example only, with reference to the drawings, in which:

FIG. 1 shows an illustration of the sputter chamber system.

FIG. 2 shows several permutations of metal and metal nitride layers, with a metal nitride layer that is imbued with a trace concentration of metal or is imbued with discrete metal particulate impurities.

FIG. 3 shows a process flow chart of inducing metal filamentation in a metal nitride layer through sputter deposition with nitrogen plasma.

FIGS. 4A, 4B, 4C and 4D illustrate several deposition methods that can be complemented with the nitrogen induced metal filamentation method. The first step generally consists of depositing non-reactive metals with nitrogen-based plasma. FIG. 4A shows co-sputtering of two different metals with nitrogen-based plasma. FIG. 4B shows a deposition process with an additional ion-implantation step. FIG. 4C shows a deposition process where the ion-implantation step occurs alongside the deposition step. FIG. 4D shows an additional chemical vapor deposition or atomic layer deposition of 2D layer.

FIG. 5 shows a cross-sectional scanning electron microscopy image of silver particles embedded in an aluminum nitride after depositing aluminum nitride on a nitrogen plasma deposition of silver.

FIG. 6A shows a Time-of-Flight Secondary-Ion-Measurement (TOF-SIMs) of the concentration profiles of silver within an aluminum nitride layer, under various deposition pressures. FIG. 6B and FIG. 6C show the surface of the aluminum nitride layer and the etched area. Blisters and discoloration can be seen. FIG. 6D shows the TOF-SIMs 3D plot of silver associated with the etched surface shown in FIG. 6C.

FIGS. 7A, 7B, 7C, 7D and 7E illustrate several designs of vertically arrayed and laterally arrayed metal/metal nitride memristor device. The device can be scaled into cross-bar or grid like devices.

FIGS. 8A, 8B, and 8C illustrate a neuronic synapse structure where lateral diffusion of metal particles can form filamentary networks. A comparison between the biological synapse and the proposed structure is shown to illustrate the analogous properties.

FIGS. 9A and 9B show how memristor networks can be abstracted into graph networks. In FIG. 9A, each vertex is associated with a memristor cell device. In FIG. 9B, each edge between graph vertices is associated with a memristor cell device.

FIG. 10 shows plots of spike-timing-dependent plasticity for memristors fabricated with 8 mTorr (A), 14 mTorr (B) and 20 mTorr (C) plasma pressure of N₂/Ar. The current growth as a function of voltage pulse trains is shown for a 14 mTorr memristor (D).

### DETAILED DESCRIPTIONS

Various embodiments and aspects of the disclosure will be described with reference to details discussed below. The following description and drawings are illustrative of the disclosure and are not to be construed as limiting the disclosure. Numerous specific details are described to provide a thorough understanding of various embodiments of the present disclosure. However, in certain instances, well known or conventional details are not described in order to provide a concise discussion of embodiments of the present disclosure.

As used herein, the terms, “comprises” and “comprising” are to be construed as being inclusive and open ended, and not exclusive. Specifically, when used in the specification and claims, the terms, “comprises’ and “comprising” and variations thereof mean the specified features, steps or components are included. These terms are not to be interpreted to exclude the presence of other features, steps or components.

As used herein, the terms “about and “approximately are meant to cover variations that may exist in the upper and lower limits of the ranges of values, such as variations in properties, parameters, and dimensions. Unless otherwise stated, the terms “about and “approximately’ mean plus or minus 25 percent or less.

As used herein, the term “dielectric” refers to any polarizable non-conductive medium, including air.

### Nitrogen Plasma Sputtering of Metal and Metal Nitride

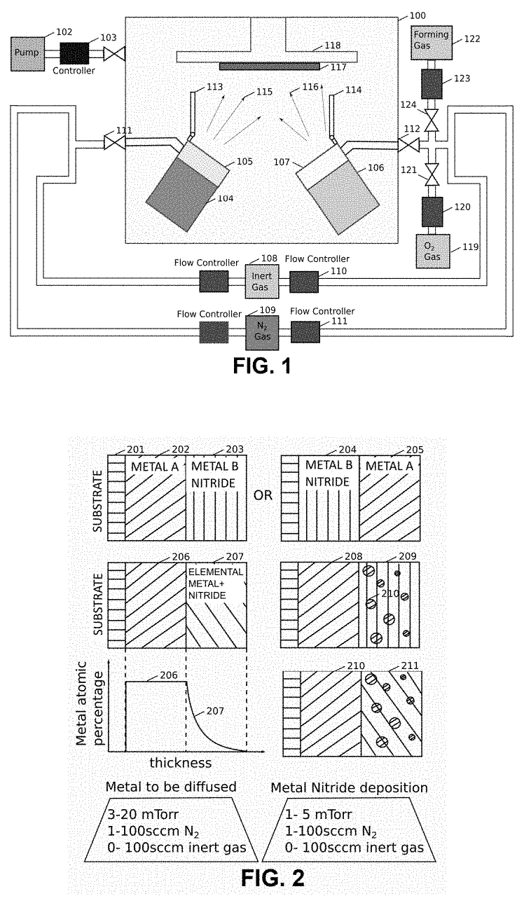

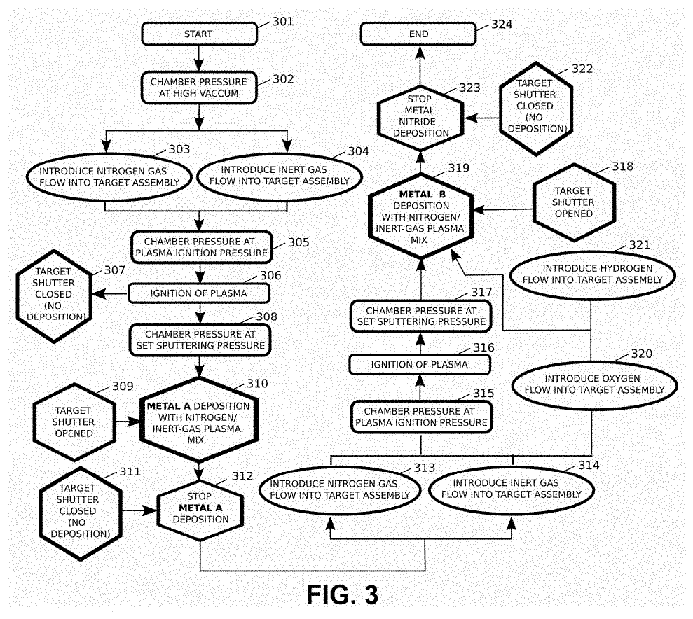

According to FIG. 1 and FIG. 3, at the start (301), the sputter chamber (100), with the KJL magnetron sputterer system as an example, is connected to a vacuum pump system (102,103) that comprises a roughing pump, turbo pump and cryo-pump to generate a pressure between low vacuum to ultra-high vacuum (302), comprise of 2 target assemblies (104 and 106) with one target containing a target material A (105) which is a metal typically non-reactive to nitrogen gas plasma and retain itself as an electrically conductive deposited metal film and another target containing a target material B (107) which is either a metal that is typically reactive to nitrogen gas plasma to form a metal nitride dielectric, or a target material B is a metal nitride that is typically a dielectric. Examples of target material A are metals such as silver, mercury, gold, platinum. Examples of B are either metals such as zironium, tungsten, vanadium nitride, tantalum nitride, nobium nitride, copper, aluminum, gallium, indium, lithium, sodium, bellyrium, magnesium, calcium, strotrium, zinc, titanium, silicon, boron, iron, palladium or their associated nitride. The target assemblies are gas fed by either or both an inert gas supply (108) and a nitrogen gas (109) supply that are respectively flow controlled by controllers (110, 111).

In the aforementioned deposition sequence, a voltage bias, and a N2/inert-gas mixed flow is initially introduced to the target assembly containing the metal A target (303)). Concurrently, the pressure of the chamber is modulated by the pump controller to reach a plasma ignition pressure (305). Plasma is ignited, with the composition of the plasma modulated by the N2/inert gas (306) while the shutter to the target assembly is shut (307). The chamber pressure is subsequently adjusted to a set sputtering pressure (308), and subsequently the shutter to the target assembly is opened (309) to allow deposition of the metal (115) onto the substrate (117, 310). The substrate undergoes a platen rotation to enable uniform thickness and deposition quality (118). After metal A deposition, the shutter is closed (311) and the gas flows are turned off by a valve (111), and power to the target assembly is set to zero (312).

The metal-nitride deposition subsequently takes place, by a similar procedure as the aforementioned N₂/inert gas modulated metal A film deposition. The target assembly containing the N₂ reactive metal B (107) has a mixture of N₂/inert-gas flow fed into it (313, 314), with a set power and the chamber pressure set to the ignition pressure (315). After ignition of the plasma (316) is achieved, the pressure of the chamber is set to a sputtering pressure (317), and the shutter (114) is opened (318) to allow metal sputtering into the ionized N₂/inert-gas plasma (116, 319). Both factors, which include the bombardment of ionized N+ onto the target surface, as well as reactive interactions between sputtered metal ions and ionized N+ within the plasma sheath, enables the sputtered metal ions to react with nitrogen ions to become metal nitride molecules. The metal nitride deposition happens on top of the N₂ modulated but unreactive metal film.

There are two additional possibilities to modify the film properties of the metal nitride, by changing the composition to a mixed metal oxy-nitride, or by introducing hydrogen in the composition of forming gas to passivate dangling bonds or neutralize electronic defects. Hence there is the possibility of introducing an oxygen gas (119, 320) to the plasma mix. The oxygen gas is fed (121, 319) into the plasma at any point in the deposition of the metal nitride. The oxygen gas flow can also be varied at any point in the deposition with a flow controller (120). Further, hydrogen gas (122, 321) can be introduced (124) into the plasma at any point in the deposition (221), which can be varied with a flow controller (123).

When the deposited material reaches the required thicknesses, the shutter (114, 322) is closed, power is reduced to zero and gas flows are shut off (111, 112, 323). The two-layer film as deposited (324) can be further processed with other depositions or be retrieved as is for device use. In another deposition sequence of metal-nitride followed by metal deposition, the same processing parameters and steps are applied, only the order of deposition is reversed.

FIG. 2 discusses the possible material compositions of the deposited 2-layer films. There are two film layers that are deposited on a substrate (201) in either sequence, a metal film deposition that is modulated by a mixed inert-gas/nitrogen gas supplied plasma (202), and a metal nitride film deposition that is modulated by a mixed inert-gas/nitrogen gas supplied plasma (203). A metal nitride can be deposited first (204), followed by a metal deposition (205).

In one sequence, that is, a metal film deposition followed by a metal nitride film deposition, a metallic film (206, 208) modulated by nitrogen or inert-gas/nitrogen plasma will induce metallic diffusion and penetration beyond the metal/metal-nitride interface and into the bulk of the metal nitride film. The diffusion of metal will take several forms within the metal nitride layer. One form is a continuous atomic concentration profile of trace metal within the metal nitride layer (207). The metal atomic concentration within the metal layer acts as the source of metal concentration gradient profile within the metal nitride (207). It can also take the form of discrete particles within the metal nitride layer (209). It can also take the form of discrete particles of metal (210) within an atomic concentration profile of trace metal within the metal nitride layer (211). FIG. 2 also shows the range sputtering parameters for the metal A deposition and metal B nitride deposition.

### Extension of Fabrication Method

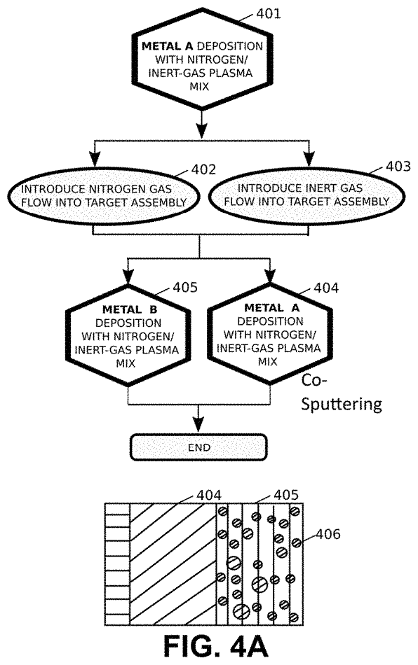

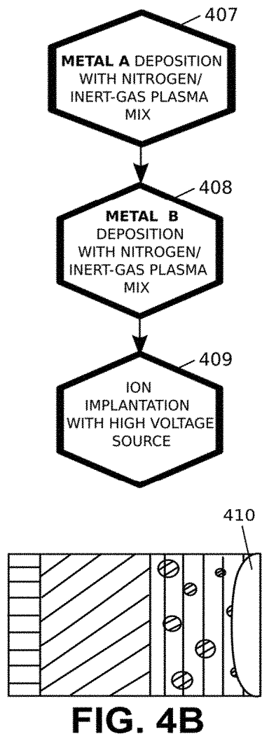

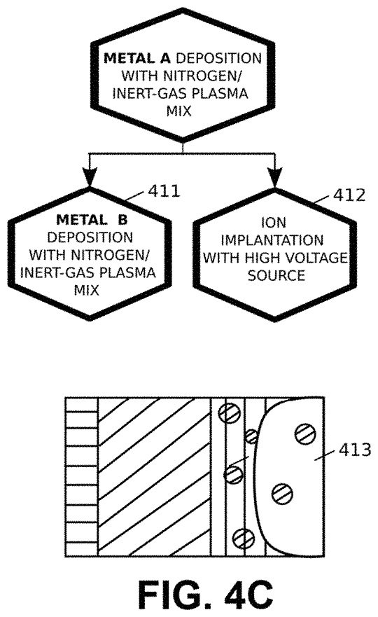

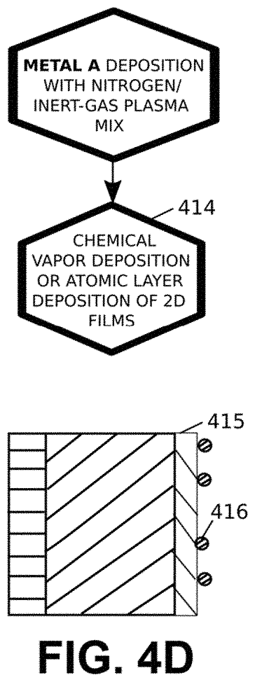

While the aforementioned fabrication method can generate metal diffusion into a nitride, there are possible extensions or modifications to the method to generate novel metal concentration profiles within the dielectric, which will result in novel memristor behaviour. FIGS. 4A-4D show four modifications to the deposition processes.

FIG. 4A shows a combination of N2/Ar sputtering and co-sputtering of 2 separate material targets. Deposition of unreactive metal A proceeds (401) with N2/inert-gas mixture, after which N2 (402) and inert gases (403) are flowed into metal A and reactive metal B target assemblies. Both metal A and B are sputtered simultaneously, such that metal A is introduced into the nitride of metal B. Thus, on a substrate, metal A (404) diffuses into the metal B nitride (405), while the presence of metal A within the nitride acts as growth sites for larger particles (406). FIG. 4B shows an additional ion implantation step. After depositing metal A (407) and B (408) with N₂/inert-gas plasma, an ion implantation step (409) of elements with smaller masses and sizes than the metal B nitride can be doped into the subsurface (410), providing a high conductive layer that can allow for an easier filamentation pathway.

FIG. 4C shows an ion implantation step (411) simultaneous with the deposition of metal B (412). The aim is to generate metallic concentrations within the ion-implantation layer (413), which can generate a denser electric field such that filamentation can proceed with a lower threshold voltage. FIG. 4D shows the chemical vapor deposition (414) of a 2-dimensional sheet of semiconductor or carbon compounds of a few atomic layers after the deposition of unreactive metal A with N2/inert gas plasma. Due to the presence of residual N₂ gases in metal A, metal filamentation can proceed through the 2D layer (415) to form metal A nanoparticles (416) on the surface of the 2D layer.

### Example of Silver Diffusion into Metal Dielectric Film

With the aforementioned sputter deposition of Ag into Aluminum nitride nano-thin films, via a N₂/Ar plasma mixture, it is possible to generate a controllable Ag nanoparticle distribution profile into the Aluminum nitride without co-sputtering. The Scanning Electron Microscope (SEM) images and Time-of-flight-Secondary-Ion-Measurements (TOF-SIMs) results are presented herein.

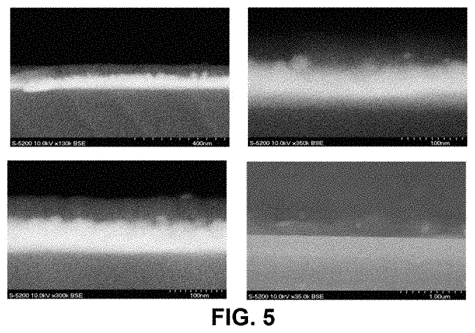

FIG. 5 shows the cross-sectional images of Ag/AlN films where the Ag is bottom layer and AlN is top layer. The N₂/Ar plasma pressure was set to 10 mTorr. It can be seen under Back-Scanning Electron mode that filamentation of Ag emerges from the Ag layer, and in some areas discrete particles of Ag are seen within the AlN layer.

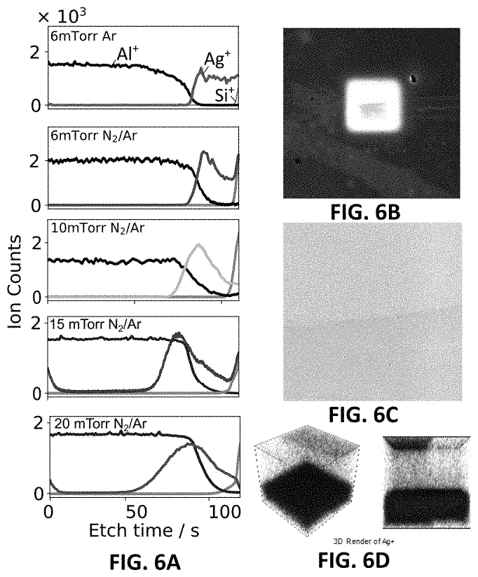

FIG. 6 shows the TOF-SIMs results of various elemental Al+, Ag+, Si+ intensity profiles as the layers are etched by Bismuth ions. FIG. 6A shows that with increasing N₂/Ar plasma pressure, the concentration profile of Ag+ extends deeper into the Al+ profile, indicating that there is silver within the AlN layer. FIG. 6B shows the surface of a sample made with 10 mTorr N2/Ar. The box indicates the etched region from which the removed ions are detected. In the immediate surrounding region, higher brightness regions are seen, with blisters or bumps spread within those regions. FIG. 6C shows the etched region where a high brightness region can be seen. FIG. 6D shows the associated 3D concentration profile of Ag+, where the higher brightness region is associated with high Ag signal. These results show that in many regions there is elemental Ag extending with significant concentrations even up to the surface of the AlN.

### Memristor Designs

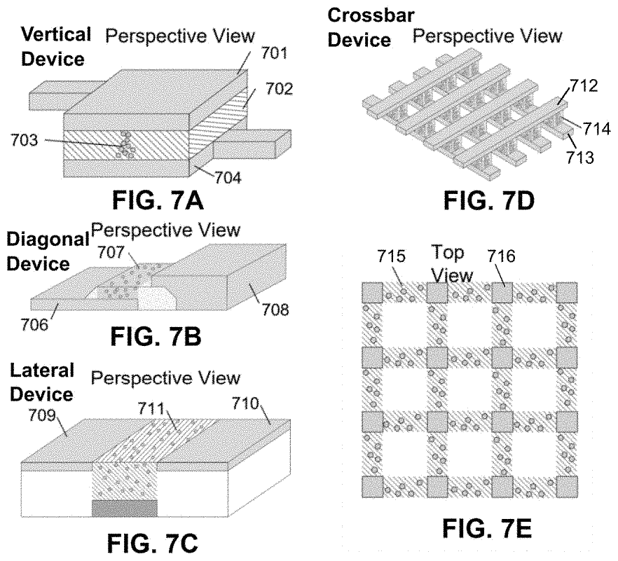

Described in FIG. 7A is a memristor composed of a dielectric switching layer (702) positioned between top (701) and bottom (704) metal electrodes in a vertical configuration. Filamentation is expected to grow vertically between the top and bottom electrodes. There is also a diagonally oriented design where filamentation is expected to grow laterally or diagonally across the dielectric switching layer (FIG. 7B) Generally, the top metal electrode (708) is positioned rightly above the bottom metal electrode (706) such that upon the application of a voltage bias across the top and bottom metal electrodes an electric field will result within the dielectric switching layer (703, 707). It is important to note that from the termination of the bottom metal electrode to the commencement of the top metal electrode there is a region where the cross-section of the device has no metal electrode. This is herein described as an offset distance. By the way of particular example, the offset distances can vary between 100 nm to 50 μm.

A laterally oriented design where the filamentation is expected to grow laterally is shown in FIG. 7C, where the electrodes (709, 710) are relatively thin films sitting opposite the switching layer (711). The layers are situated on electrically insulating and mechanically robust substrates or films, to minimize leakage current. The application of an electric field to this device between the top and bottom electrodes results in the diffusion of metal nanoparticles across the surface of the metal dielectric region and the formation of filaments originated from the bottom layer. The formation of the filaments occurs oriented along the diagonally imposed electric field. The diffusion from metal nanoparticles from the surface is in the direction from the termination of the top metal electrode from the side closest to the bottom metal electrode to the region on the surface of the dielectric switching layer directly above the bottom electrode.

By the way of particular example, a memristor device may be biased at 0 Volts at the top metal electrode and 1 Volt at the bottom metal electrode such that gradient is established within the dielectric switching layer. As another particular example, a memristor device may be biased at 0 Volts at the top metal electrode and −1 Volt at the bottom metal electrode. More specifically, the memristor device described in this embodiment consists typically of bottom metal electrode composed of Ag followed by a dielectric switching layer as described in the deposition process of the preceding section and terminated by a top metal electrode which is formed by an inert metal such as gold (Au). Application of a voltage bias is done at values not surpassing 1 Volt and for which the positive bias is denoted to be at the bottom metal electrode and the negative bias at the top metal electrode.

A dielectric switching layer is denoted as adjoining the top metal electrode and the bottom metal electrode. The formation of the dielectric switching layer is such that it supports the formation of a conductive filament formed within as a result of the application of the voltage bias described previously. The agglomeration of the metal nanoparticles originated from the deposition method described before in FIG. 3, is the mechanism by which the conductive filament is formed. Initially, the device is non-conductive or may be conductive and have a very high resistive state. Upon the application of an electric field of sufficient magnitude for a sufficient length of time, the conductive state is reached as a result of the formation of a conductive filament. It should be understood that the dielectric switching layer may also extend protrude beyond the defined geometry of the top and bottom metal electrode

As described aforementioned, this switching layer is porous or mechanically weakened by the introduction of N₂/Ar plasma so as to enable pathways for which metal filamentation can occur facilely. When a voltage bias is introduced, metal diffusion and subsequent agglomeration occurs such that a metallic conductive filamentation wire is generated within the metal nitride (DSL) layer. The resistance of the DSL decreases as the silver filamentation grows towards the opposite electrode.

With reference now to FIG. 7D, there is presented a schematic of a crossbar device according to an embodiment. It comprises a sequence of parallel top (712) and bottom (713) crossbar electrodes which oriented perpendicularly to one another. The electrodes do not encounter one another and instead are separated by dielectric switching layers (714). It is important to note that the two layers form an intersecting array. During operation, a voltage gradient is present in the dielectric switching layer between the biased top and bottom crossbar electrodes. It is important to note that reference to a crossbar is made to mean a metal electrode that may extend for a significant length so as to be normal to the boundary of one or more dielectric switching layers (714). It is also important to note that individual memristor elements as in FIG. 7A are made at the intersections of these crossbars.

Turning now to FIG. 7E, the embodiment referenced illustrates a crossbar device in a diagonal or lateral configuration. In, this memristor device is initially composed of a bottom source metal electrode followed by a dielectric switching layer (715). Both are deposited according to process outlined in the preceding section and according to cells of FIG. 7B or FIG. 7C. There are two opposing top metal electrodes that are deposited so as to not overlap the dielectric switching layer (716) that is immediately above the bottom metal electrode. These may be fabricated via reactive ion etching processes to extend into the dielectric region that was deposited or may protrude above that dielectric region. It is important to note that the presence of metal nanoparticles and a continuous metal concentration may be present at the surface of the dielectric switching layer. Similar to the behaviour of the diagonal or lateral device, upon the application of a voltage bias between the top metal electrodes, a field gradient will be established within or near to the surface of the dielectric switching layer which will cause the formation of conductive filaments. Again, with the formation of conductive filaments, the dielectric switching layer will transform from a non-conductive or high resistive state to a conductive or low resistive state. It is to be noted that the conductive filaments will form laterally or diagonally as opposed to vertically as was described previously.

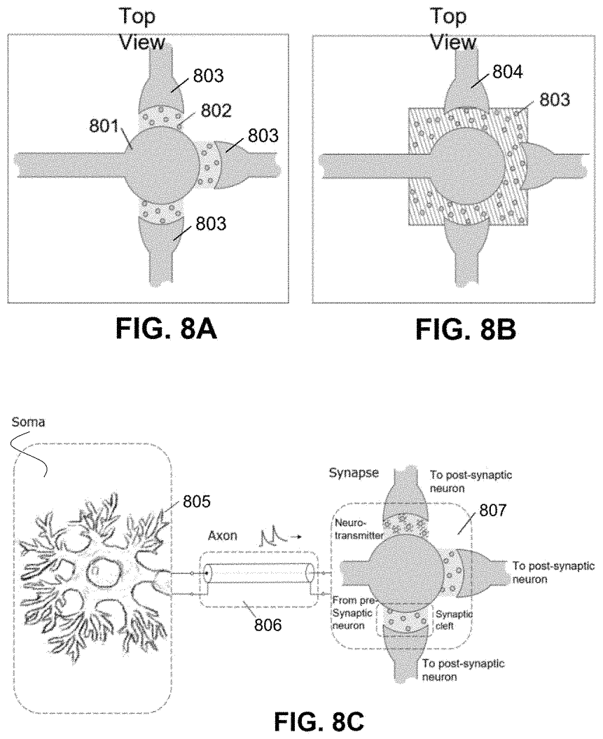

Now with reference to FIG. 8A and FIG. 8B, a device is described where the electric field within the surface of a dielectric switching layer is modulated by adjacent metal electrodes on its surface. Reference is made to the center electrode (801) to act a pre-synaptic terminal and perimeter electrodes (803) as post-synaptic terminals. The post-synaptic terminals are biased in such a way that the electric field lines emanate from the center electrode to the perimeter electrodes. In this region, a dielectric switching layer fabricated via the aforementioned sputtering method so as to possess metal nanoparticles (802, 803) on the surface. The dielectric region in FIG. 8A is connected only between the pre-synaptic and post-synaptic terminals. The dielectric region in FIG. 8B is a single region where the switching layer can have metal nanoparticles between all terminals. By the way of particular example, in FIG. 8A the post-synaptic terminals may be biased at 0 V and the pre-synaptic terminal might be biased at 2V so as to cause the diffusion of metal nanoparticles between the electrodes.

FIG. 8C shows an embodiment of the implementation of a neuron with laterally diffusive memristors. A spiking circuit takes on the analogous role of the neuron soma that produces spiking trains as a response to a bias potential. The electrical potentials are transported to the synapse via a transmission line that plays the role of the axon. Pre- and post-synaptic neurons meet at the synapse which is represented by a lateral junction memristive circuit. The silver nanoparticles that are present in the areas between the pre- and post-synaptic neuron electrodes play a role akin to that of neurotransmitters. When a potential spiking signal arrives at the pre-synaptic terminal a potential difference in generated in the regions consisting of the synaptic cleft. Follow this, Ag nanoparticles as neurotransmitters carry the signal towards the post-synaptic terminal. The post-synaptic terminal then sees an increased current spike in response to this behaviour and thus the neuron spike is carried through the neuronal network.

### Application to Graph Theory

A graph is a common data structure which consists of a set of vertices and a set of edges connecting those vertices. Graphs are used to represent networks in a wide variety of applications including geographical information systems (GIS), communication networks and computer architecture. Since many graph algorithms scale exponentially with the size of the graph, accelerating read/write operations using the memristor presented in this patent can significantly improve runtime.

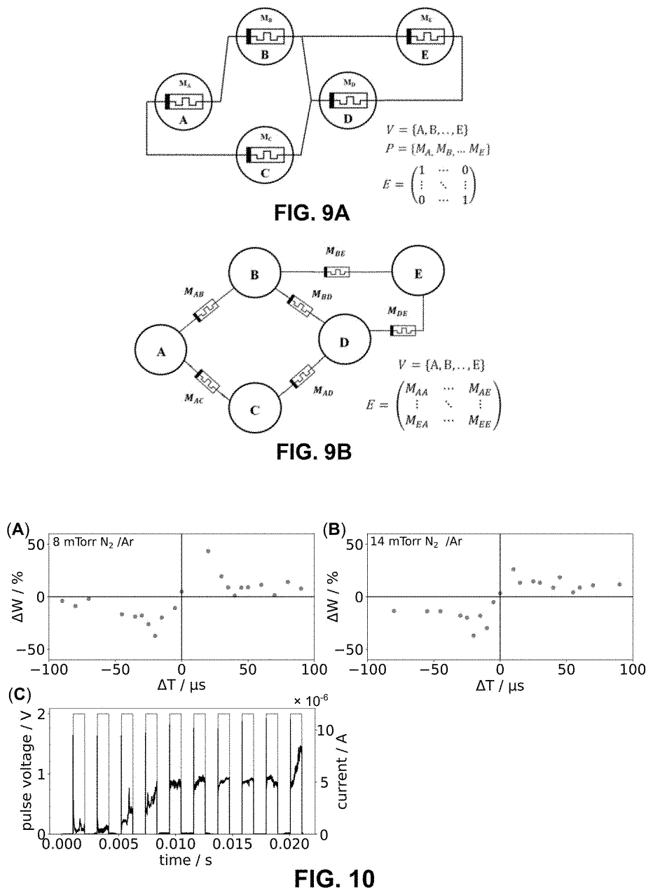

With reference to FIG. 9A, a possible graph implementation uses memristors to store vertex properties. Each vertex A is associated with a memristor possessing memristance M_{A}. The memristance represents a binary or multi-state property of the vertex. Binary properties are represented by the generic ON/OFF states of the device. Multi-state properties can be represented by the memristor's threshold voltage which varies among cycles. Using memristor storage, these properties can be accessed and updated simultaneously without the limits of von Neumann architecture.

### Graph Colouring

Graph colouring is the problem of assigning colour values to vertices in a graph such that no adjacent vertices share the same colour. Using memristors, the threshold voltages represent the multi-state property of colour. By applying voltage cycles to vertex memristors, the threshold voltages can be modulated to new colour values.

The most common graph colouring algorithm takes a greedy approach. First, the lowest valued colour (commonly a state of 0) is assigned to a vertex. Then, all adjacent vertices are assigned the lowest possible colour that is not present in any adjacent vertex. If all available colours are used on the vertices adjacent to that vertex, then a new colour is added.

Using Ag/AlN memristors, voltage cycles can be applied to vertices to decrease their threshold voltage. This allows the algorithm to read and write to memory in the same location. Since a graph colouring algorithm on a large, connected graph can perform millions of colour updates, the improvement in update speed will improve runtime. Once the algorithm is complete, the threshold voltage level of a vertex can be converted to an integer colour property by extracting the number of cycles applied.

### Cycle Detection

Another graph application of the Ag/AlN memristors is in cycle detection. In cycle detection, a depth-first search is performed on the graph to find back edges. A back edge is an edge connecting a vertex to another vertex on the search stack. If a graph has a back edge, then it is cyclic.

Each vertex can have an associated memristor possessing memristance M. When the vertex is not on the search stack, its memristor will be in the OFF (high resistance) state. Once the vertex is added to the stack, a voltage sweep is applied and the memristor switches to its ON (low resistance) state. As the search continues, a back edge can easily be detected by a short circuit from a new vertex to one already on the stack. Once a vertex has been expanded, its memristance can return to the OFF state by returning the voltage to zero.

### Minimum Spanning Trees

Memristor implementations can also be used to set edge properties in a graph. With reference to FIG. 9B, each edge between graph vertices A and B can contain an associated memristor with memristance M_{AB}. Accessing and updating the edge property can therefore be made more efficient than in a traditional von Neumann architecture. When representing edge properties with the Ag/AlN memristor, we can connect the memristor between vertices in parallel with a large resistor. By including the resistor, we set a predefined OFF state resistance between the two vertices.

An application of memristor edge storage can be found in minimum spanning tree (MST) algorithms. An MST is a set of weighted edges which connects every vertex in the graph together at a minimal cost. The primary algorithm, Prim's algorithm, takes a greedy approach where the lowest weighted edge connecting to a vertex not included in the current MST is added each iteration. With V vertices in a graph, this approach can be run V-1 times to construct the complete tree.

Using memristors, we can store the binary property of whether or not the edge is included in the MST. Representing inclusion as the OFF state will prevent the tree from including the edge again, while available edges will be set with an ON resistance. This implementation will allow for rapid computation of the MST by updating edge values by their associated memristance.

### EXAMPLES

The following examples are presented to enable those skilled in the art to understand and to practice embodiments of the present disclosure. They should not be considered as a limitation on the scope of the disclosure, but merely as being illustrative and representative thereof.

### Examples of a Memristor Device Fabricated with Said Method

FIG. 10 show STDP time-window plots where potentiation occurs when the synaptic event occurs before the postsynaptic spike. The relative change (ΔW) in potential difference from negative to positive values of the time range is an indication of the strength of the synapse. The relative change is high for the low pressure memristor (A) and is lower for the higher pressure memristor (B). Thus it can be shown that the strength of the synapse can be increased with higher plasma pressures. The increase in electrical conductance with increasing sequence of 2V pulses is shown in (C). Several pulses were needed to turn on the device, and the response intensity of the current pulses increases as the silver filamentation develops a coherent bridge between top and bottom electrodes.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

Therefore, what is claimed is:

1. A method of physical deposition process that enables metallic diffusion into a metal nitride layer, via the aid of a modulated nitrogen/inert-gas plasma or flow stream, in order to build the active components of memristor devices. The method comprises:
a nitrogen and inert gas mixture to form the plasma composition;
further comprising a chamber pressure to modulate the interaction of the plasma with the metal deposition vapor;
further comprising a power setting of the metal target assembly to modulate the deposition rate of the metal;
further comprising depositing the metal nitride layer by reactive sputtering of a reactive metal with plasma comprising nitrogen or nitrogen/inert gas; and
further comprising depositing a metal nitride layer on top of the metal layer or depositing a metal layer on top of a metal nitride layer, or depositing the metal nitride layer by sputtering a metal nitride target with the nitrogen-based plasma.

2. The method of claim 1, wherein the active layer has metal diffusion into the metal nitride layer that comprises:
a concentration profile of metal within the metal nitride;
further comprising the elemental metal profile is electrically conductive and enables a continuous or semi-continuous electrical pathway or discrete metal particles within the metal nitride;
further comprising elemental metal or metal particles in the metal nitride layer, are non-oxidized and are non-nitridized.

3. The method of claim 2, wherein, under a voltage bias, the elemental metal and/or metal particles form a filamentary or dendritic electrical conductive network within the metal nitride layer;
further comprising under a reversed voltage bias, the conductive network reforms to form a discontinuous and non-conductive electrical network within the metal nitride layer.

4. The method according to claim 1, wherein oxygen gas is introduced to the sputtering of the metal nitride or reactive metal in nitrogen plasma at any point in the deposition;
further comprising setting the flow rate of oxygen gas and varying it at any point in the deposition;
further comprising the metal nitride composition has a profile of metal oxy-nitride composition within the metal nitride;
further comprising a metal diffusion into the metal oxy-nitride layer;
further comprising an elemental (trace amounts) concentration profile of metal within the metal oxy-nitride layer or discrete metal particles within the metal oxy-nitride layer.

5. The method according to claim 1, wherein additional processes are employed to modulate a concentration profile of metal within the metal nitride, comprising or more one of:
co-sputtering of another metal or the metal that is of the underlying layer, with the metal nitride layer;
ion implantation of a dopant material such as Si, Ge, Ga, Bi, Zr, Er, Au, Pt, Li, P, In after or during the deposition of the metal nitride layer;
sputtered or implanted elements forming alloys and eutectics where concentration dependent chemistry can be appropriately availed in various ways including ionic transport;
chemical vapor deposition, or plasma assisted chemical vapor deposition, of atomically thin two-dimensional films on the metal layer that is to be diffused;
further comprising the metal diffusion emerges through the two-dimensional film to form a surface layer of metal on the film.

6. The method according to claim 1, wherein the active layer comprises various metal nitrides, metalloid nitrides and non-reactive metals to nitrogen-based plasmas
further comprising the metal nitride layer are nitrides of aluminum, silicon, gallium, zirconium nitride, titanium nitride, magnesium nitride, lithium nitride; and
further comprising the metal that diffuses into the nitride layer are silver, gold, platinum, copper, manganese, vanadium, chromium, nickel, zinc, indium, lead.

7. The method of claim 2, wherein a negative electrode is the metal layer, and the positive electrode is located on the top of the dielectric layer with a lateral offset, such that filamentation will have to occur diagonally within the dielectric layer;
further comprising metal particles can emerge on the surface of the dielectric layer under a voltage bias;
such that the surface metal particles can diffuse laterally on the surface to form a lateral filamentation structure.

8. The method of claim 2, wherein the electrodes are laid laterally across the dielectric nitride layer with a gap;
further comprising the gap ranges from 50 nm to 50 μm;
further comprising metal diffusion occurs within the nitride layer under a lateral voltage bias;
further comprising metal particles can emerge on the surface of the metal nitride layer; and
further comprising the surface metal particles can diffuse laterally on the surface of the metal nitride to form a lateral filamentation structure under the lateral voltage bias.

9. The method of claim 1, wherein a cross bar array can be used to scale up the device into a memristor network, which comprises:
a metal electrode is laid below or is part of the active layer of metal/metal-nitride;
further comprising a metal electrode is laid above the active layer;
further comprising the bottom and top electrodes are linked to other metal/metal-nitride/metal devices in a cross-wise pattern; and
further comprising the cross-bar array can be layered vertically.

10. The method of claim 8, wherein a grid-like pattern can be used to scale up the device into a memristor network, which comprises:
the metal electrodes spaced laterally across a nitride/metal layer;
further comprising the distance between the electrodes ranges from 50 nm to 10 μm; and
further comprising metal particles can emerge from the surface of the dielectric layer and diffuse laterally between electrodes.

11. The method of claim 8, wherein a spiking circuit can be implemented, which comprises:
an electrode that is a transmission line;
1 to 5 electrodes that are laterally across the transmission line electrode; and
further comprising when a spiking potential is sent through the electrodes, metal diffusion occurs between the electrodes such that a current spike is achieved.

12. A machine implemented method of storing a range of values within a memristor network according to claim 9, which comprises:
the threshold voltage of each memristor device can be modulated to represent a plurality of states;
further comprising the threshold voltages can be modulated through repeated cycles;
further comprising each memristor device represents a colour associated with ‘on’ and ‘off’ states; and
further comprising the ensemble of memristor devices can be represented as a graph of vertices.

13. A machine implemented method of graph colouring with a greedy approach according to claim 12, which comprises:
an initial operation where the lowest valued coloured value is assigned to a vertex;
further comprising all adjacent vertices are assigned a colour of the lowest possible value that is not present in an adjacent vertex;
further comprising evaluate all adjacent vertices and determine which colours are unavailable;
further comprising new colours are added after all possible colours are assigned; and
further comprising after the completion of the algorithm, the threshold voltage of each vertex is converted to an integer by evaluating the number of cycles applied.

14. A machine implemented method of minimum spanning tree of weighted graphs with a greedy approach according to claim 12, which comprises:
each vertex can be stored in a binary on or off state;
further comprising the shortest edge is evaluated which also does not generate a cycle with adjacent edges; and
further comprising the available edges will be set to the on state while non-available edges are set to the off stage so that the tree does not include those edges.
